(19) United States
(12) Patent Application Publication
(10) Pub. No.: US 2025/0007151 A1
(43) Pub. Date: Jan. 2, 2025

(54) ELECTROMAGNETIC WAVE RESONANT STRUCTURE, METHOD FOR PRODUCING ELECTROMAGNETIC WAVE RESONANT STRUCTURE, ELECTRONIC COMPONENT, AND CONDUCTIVE STRUCTURE

(71) Applicants: Ryuya Mashiko, Tokyo (JP); Yohei Shiren, Tokyo (JP); Shinichi Hatanaka, Tokyo (JP); Yukiko Abe, Kanagawa (JP)

(72) Inventors: Ryuya Mashiko, Tokyo (JP); Yohei Shiren, Tokyo (JP); Shinichi Hatanaka, Tokyo (JP); Yukiko Abe, Kanagawa (JP)

(73) Assignee: Ricoh Company, Ltd., Tokyo (JP)

(21) Appl. No.: 18/754,814

(22) Filed: Jun. 26, 2024

(30) Foreign Application Priority Data
Jun. 29, 2023 (JP) 2023-107166

(51) Int. Cl. H01Q 1/38; H01Q 1/42

(52) U.S. Cl. CPC H01Q 1/38; H01Q 1/42

(57) ABSTRACT

An electromagnetic wave resonant structure is provided that includes a conductive portion and a non-conductive portion, and the non-conductive portion includes a mixed region of a part of the conductive region and an insulator.

### CROSS-REFERENCE TO RELATED APPLICATIONS

This patent application is based on and claims priority pursuant to 35 U.S.C. § 119(a) to Japanese Patent Application No. 2023-107166, filed on Jun. 29, 2023, in the Japan Patent Office, the entire disclosure of which is hereby incorporated by reference herein.

### BACKGROUND

### Technical Field

The present disclosure relates to an electromagnetic wave resonant structure, a method for producing an electromagnetic wave resonant structure, an electronic component, and a conductive structure.

### Related Art

The frequency of electromagnetic waves used in a 6G communication, an imaging field, or the like is 0.1 THz to 10 THz. As a pattern structure that absorbs such electromagnetic waves in a terahertz band (also called terahertz waves), a split-ring resonator (SRR), which is one of the representative resonator elements used in a metamaterial, is known. The unit cell size of the SRR is approximately 100 μm, and the line width forming the SRR is from several μm to several tens of m.

A structure with such a line width can be produced using super inkjet. However, a single nozzle using capillary is commonly used despite having lower productivity than inkjet. Further, it is necessary to control the gap (potential difference) between the nozzle and an object to be coated more precisely than with inkjet.

On the other hand, a method is known in which a ring-shaped pattern with a line width of 10 μm or less is formed by an inkjet method using the coffee stain effect.

### SUMMARY

An electromagnetic wave resonant structure according to one aspect of the present invention includes a conductive portion and a non-conductive portion, and the non-conductive portion includes a mixed region of a part of the conductive region and an insulator.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a diagram illustrating a split-ring resonator (SRR);

FIG. 2 is a diagram illustrating a method for confirming conductivity in a mixed region where a metal region and a resin region overlap;

FIG. 3 is a schematic configuration diagram of an inkjet device;

FIG. 4 is a diagram illustrating a state in which a resin ink is being discharged onto a substrate;

FIG. 5 is a diagram illustrating a resin ink discharged onto the substrate;

FIG. 6 is a diagram illustrating a state in which a metal ink is being discharged onto a substrate on which a resin ink has been discharged;

FIG. 7 is a diagram illustrating a resin ink and a metal ink discharged onto a substrate;

FIG. 8 is a diagram illustrating a state in which a part of a metal ink overlaps a part of a resin ink on a substrate;

FIG. 9 is a diagram illustrating a first embodiment;

FIG. 10 is a sectional diagram taken along a line A-A in FIG. 9;

FIG. 11 is a diagram illustrating a state in which a metal ink is being discharged onto a substrate;

FIG. 12 is a diagram illustrating a metal ink discharged onto a substrate;

FIG. 13 is a diagram illustrating a state in which a resin ink is being discharged onto a substrate on which a metal ink has been discharged;

FIG. 14 is a diagram illustrating a metal ink and a resin ink discharged onto a substrate;

FIG. 15 is a diagram illustrating a state in which a part of a resin ink overlaps a part of a metal ink on a substrate;

FIG. 16 is a diagram illustrating a second embodiment;

FIG. 17 is a sectional diagram taken along a line B-B in FIG. 16;

FIG. 18 is a diagram illustrating a hydrophilic portion in which a part of a substrate is subjected to a hydrophilic treatment;

FIG. 19 is a diagram illustrating a resin ink discharged onto a hydrophilic portion of a substrate;

FIG. 20 is a diagram illustrating a third embodiment;

FIG. 21 is a diagram illustrating a fourth embodiment;

FIG. 22 is a diagram illustrating a state in which a plurality of SRRs are fixed with a resin;

FIG. 23 is a diagram illustrating a fifth embodiment;

FIG. 24 is a diagram illustrating a sixth embodiment;

FIG. 25 is a diagram illustrating an SRR with two non-conductive portions;

FIG. 26 is a diagram illustrating a seventh embodiment;

FIG. 27 is a diagram illustrating an eighth embodiment;

FIG. 28 is a diagram illustrating a conductive structure; and

FIG. 29 is a cross-sectional diagram taken along a line C-C in FIG. 28.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

A resonator element such as SRR includes a ring portion and a split portion to absorb electromagnetic waves. In a ring formation method using the coffee stain effect, the split portion cannot be formed, making it difficult to obtain a structure that absorbs terahertz waves.

According to one aspect of the present invention, an electromagnetic wave resonant structure that can absorb terahertz waves is provided.

Embodiments of the present invention are described below with reference to the drawings. Note that common parts in each drawing are given the same or corresponding reference numerals, and the description thereof may be omitted.

### Electromagnetic Wave Resonant Structure

### First Embodiment

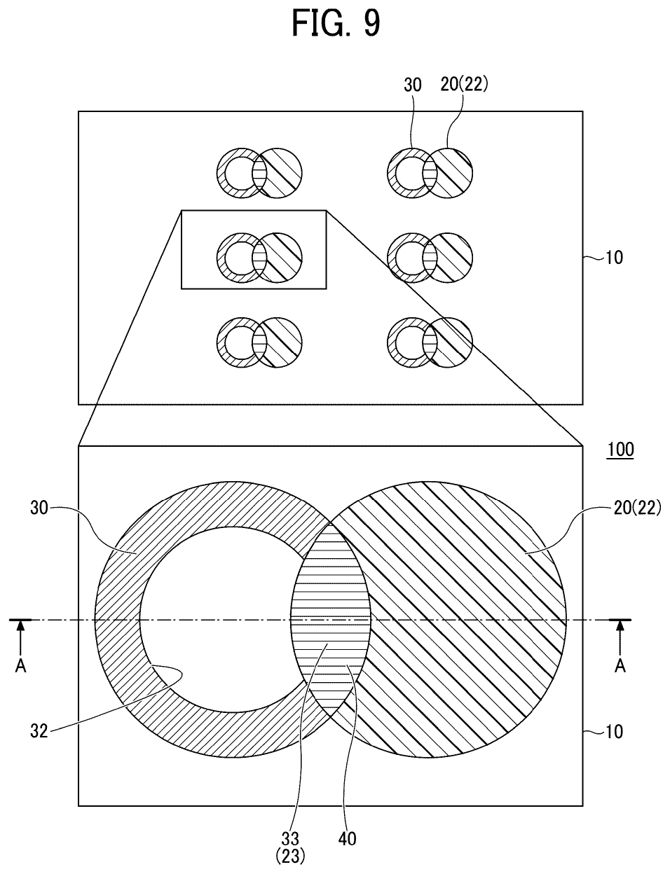

An electromagnetic wave resonant structure 100 of a first embodiment, illustrated in FIG. 9, includes a conductive portion and a non-conductive portion.

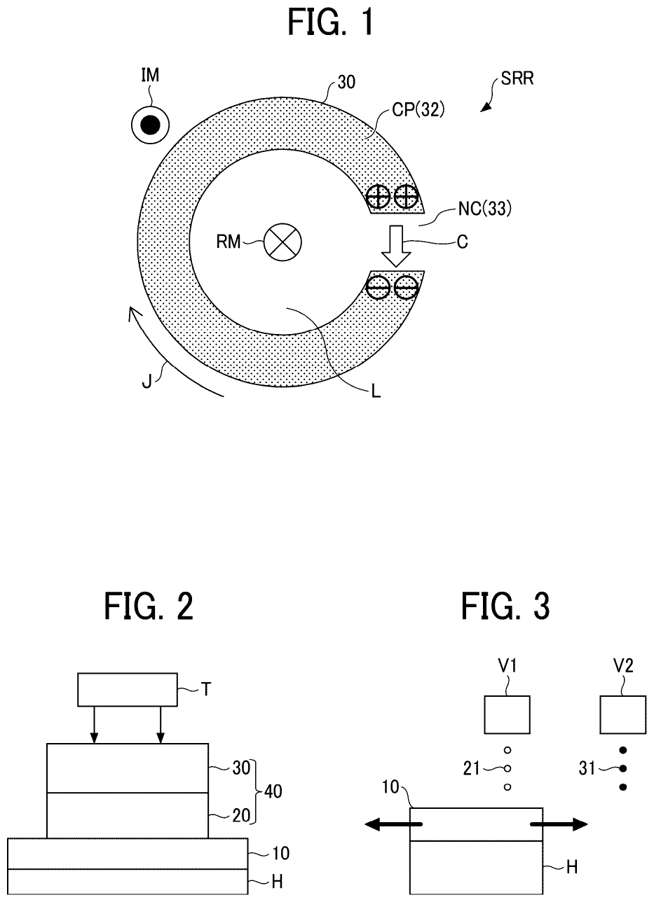

The electromagnetic wave resonant structure is, for example, a split-ring resonator (SRR) illustrated in FIG. 1. The SRR includes a ring portion (conductive portion) CP having a ring shape in a plan view and a split portion (non-conductive portion) NC formed between both ends of the ring portion CP. The ring portion CP forms a reactance L, and the split portion NC forms a capacitance C (capacitor), thereby forming a closed circuit of LC resonance. In the SRR, incident electromagnetic waves are absorbed by virtue of LC resonance.

Specifically, as illustrated in FIG. 1, when an electromagnetic wave (incident magnetic field) IM whose magnetic field component vibrates in a perpendicular direction relative to a plane including the SRR is applied, an induced current J, which creates a counter magnetic field RM that cancels the incident magnetic field by electromagnetic induction, flows along the ring portion CP. On the other hand, positive and negative charges are accumulated in the split portion NC. When these charges flow to the ring portion CP via the capacitance C, a closed circuit of LC resonance is formed within the SRR structure.

In this case, a resonant frequency f₀ of the SRR is given by a formula 1.

$$[ Mathematical 1 ]$$

$${f}_{0} = 1 / 2 π √ CL \qquad ( 1 )$$

The conductive portion is a region formed by a conductor. As the conductor forming the conductive portion, a metal is preferably used. That is, the conductive portion is preferably a metal. When the conductive portion is the metal as described above, it becomes possible to apply the conductive portion of the electromagnetic wave resonant structure to the ring portion CP (conductive portion) of the SRR.

The type of metal is not particularly limited. However, examples thereof include silver (Ag), copper (Cu), gold (Au), aluminum (Al), magnesium (Mg), tungsten (W), molybdenum (Mo), zinc (Zn), nickel (Ni), and an alloy of two or more of these metals.

Of these, silver or a silver alloy is preferable because of its high conductivity.

Further, a material used for the conductor forming the conductive portion is not limited to the metal, and a conductive material other than the metal may be used. Examples of the conductive material other than the metal include a ferroelectric material such as lead zirconate titanate (PZT), conductive carbon such as graphene or a carbon nanotube, a conductive composite oxide such as indium tin oxide (ITO), and a conductive polymer such as polyethylene dioxythiophene (PEDOT).

The conductive portion preferably has a ring shape in a plan view. Forming the conductive portion into such a ring shape allows the conductive portion to form the ring portion of the SRR when the electromagnetic wave resonant structure including the conductive portion is applied to the SRR.

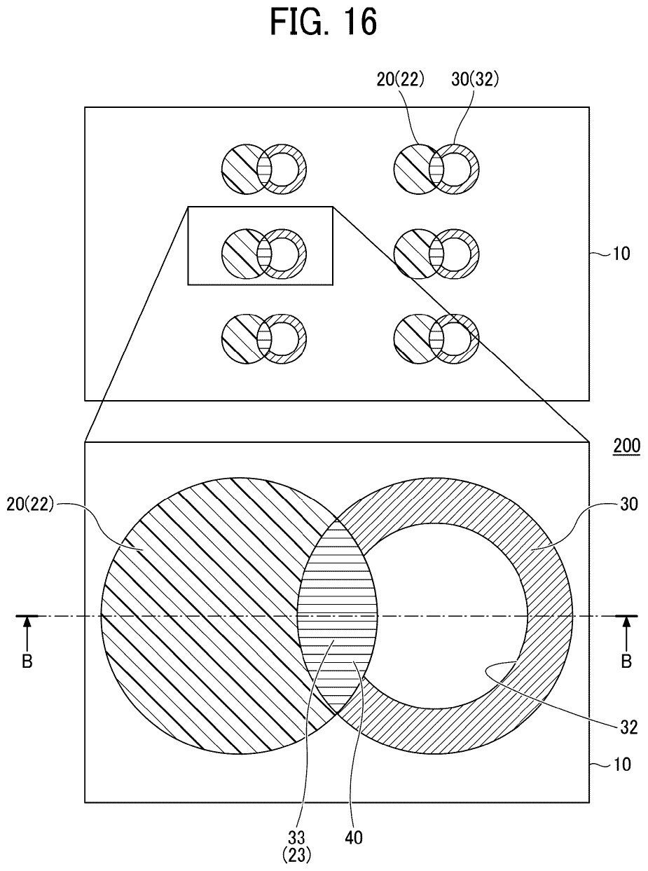

Further, the ring-shaped conductive portion in the plan view is preferably formed using the coffee stain effect. In the present specification, the coffee stain effect refers to a phenomenon in which when a droplet of coffee or the like is dried, the outer edge (periphery) of the droplet evaporates more than the other parts, causing the liquid to flow toward the periphery to compensate for the evaporation, resulting in forming a film in the periphery after drying (see FIG. 9 illustrating a first embodiment and FIG. 16 illustrating a second embodiment).

Note that when a metal particle ink including an Ag particle (hereinafter referred to as a metal ink) is discharged by inkjet onto a substrate (e.g., a glass substrate) heated to 120° C., a thin ring-shaped line is formed in a plan view due to the coffee stain effect. It has been found that the line width of this thin line is approximately several tens of m, making it possible to achieve dimensions that can absorb electromagnetic waves in a terahertz band (terahertz waves).

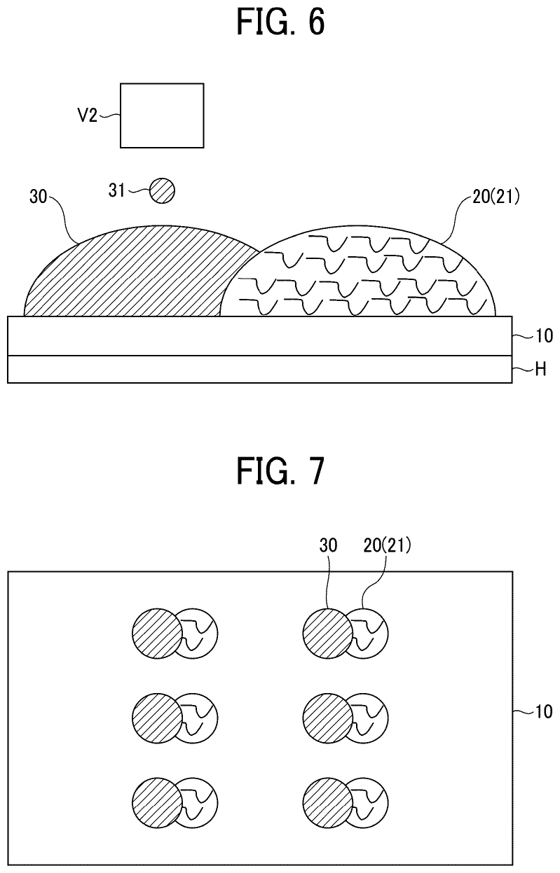

The conductive portion is formed by discharging a conductive ink. In the present embodiment, as illustrated in FIG. 6 to FIG. 8, a metal ink 31 is discharged onto a substrate 10 having a resin ink discharged thereon, and as this metal ink 31 is cured, a metal region 30 including a metal M is formed on a substrate 10). In this embodiment, the metal region 30 is an example of the conductive portion, and the metal ink 31 is an example of the conductive ink.

The non-conductive portion is a region that does not exhibit conductivity. As a material forming the non-conductive portion, an insulating material such as a resin or glass is used, and a resin is preferably used.

The type of resin is not particularly limited. However, examples thereof include a curable resin such as an acrylic, epoxy, polyimide, polyamide, or polyimide amide resin. These resins may be used alone or in combination of two or more.

The thickness of the non-conductive portion is not particularly limited and can be appropriately selected according to the purpose. Note that, as described below, it is preferable to control the thickness of the non-conductive portion so that when the resin ink 21 is cured to form a resin region 20, and the metal ink 31 is cured to form the metal region 30, a part of the resin ink 21 remains uncured.

The non-conductive portion optionally includes a filler, a polymerization initiator, a polymerization inhibitor, a surfactant, a colorant, or the like as other components.

The non-conductive portion is formed by discharging a non-conductive ink. In the present embodiment, as illustrated in FIG. 6 to FIG. 9, the resin ink 21 is discharged onto the substrate 10, and as this resin ink 21 is cured, the resin region 20 is formed on the substrate 10, and a portion 23 of the resin region 20 forms the non-conductive portion. In this embodiment, the resin region 20 is an example of an insulator, the portion 23 of the resin region 20 is an example of the non-conductive portion, and the resin ink 21 is an example of the non-conductive ink.

The non-conductive portion includes a region where the insulator is mixed in a part of the conductive portion (hereinafter referred to as a mixed region).

A material for the insulator is not particularly limited. However, the material is preferably a resin. The type of resin is not particularly limited. However, examples thereof include a curable resin such as an acrylic, epoxy, polyimide, polyamide, or polyimide amide resin. These resins may be used alone or in combination of two or more.

The insulator is formed by the resin, thus the non-conductive portion of the electromagnetic wave resonant structure can be applied to the split portion (non-conductive portion) of the SRR.

In the first embodiment illustrated in FIG. 9, a mixed region 40 is a region in which the ring-shaped conductive portion in the plan view and the circularly shaped insulator in the plan view overlap.

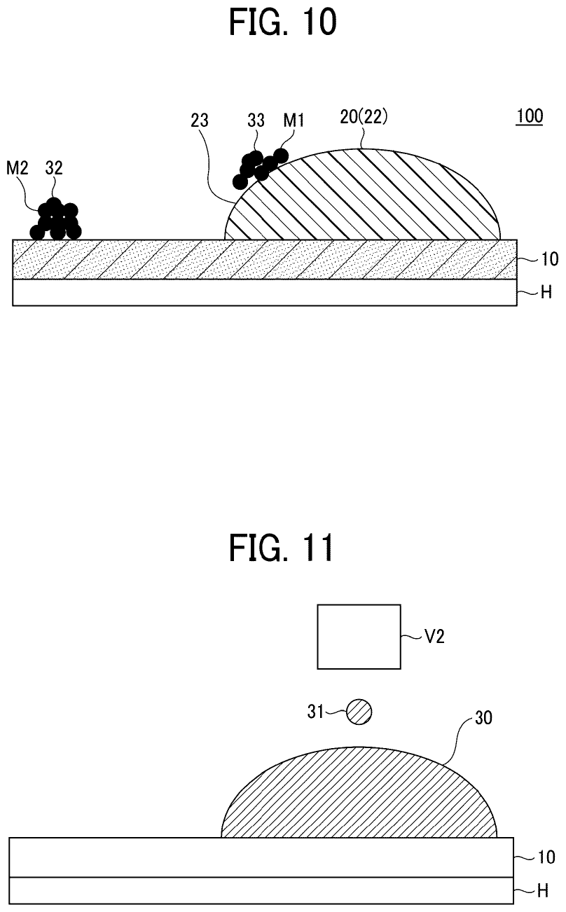

In the mixed region 40 of the first embodiment illustrated in FIG. 9, a portion 33 (metal M1) of the ring-shaped metal region 30 in the plan view is laminated on the portion 23 of the circularly shaped resin region 20 in the plan view as illustrated in FIG. 10, and the metal M1 laminated on the resin region 20 is insulated from a metal region 32 (metal M2) not laminated on the resin region 20.

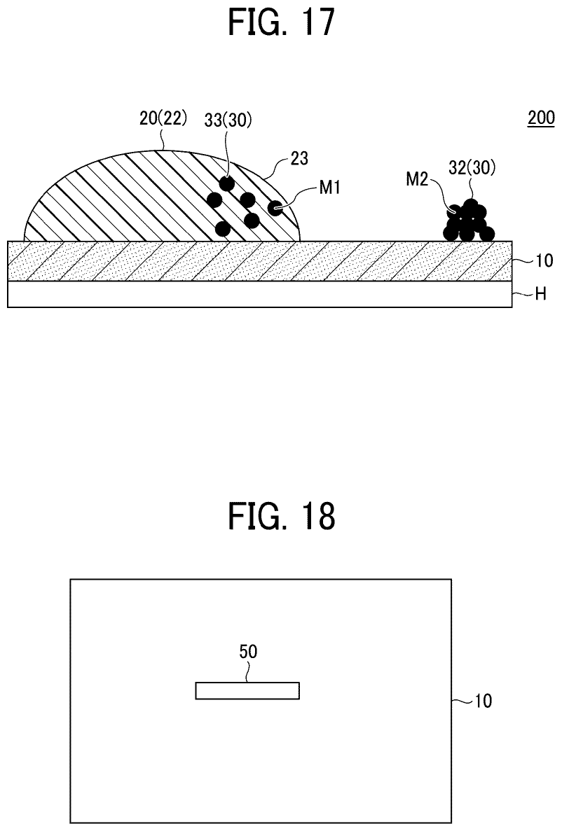

Further, in the mixed region 40 of the second embodiment illustrated in FIG. 16, the portion 33 (metal M1) of the metal region 30 is taken into the resin region 20 as illustrated in FIG. 17, and the metal M1 taken into the resin region 20 is insulated from the metal region 32 (metal M2) that is not laminated on the resin region 20.

The conductivity was confirmed for such mixed regions. As illustrated in FIG. 2, the substrate 10 (e.g., a glass substrate) was placed on a heater H (e.g., a stage heater), a resin ink including an acrylic resin was dropped onto the substrate 10 heated to 120° C., a metal ink including an Ag particle was further dripped onto the resin ink, and the metal ink was also cured by heating at 120° C., thereby forming the mixed region 40 in which the metal region 30 was laminated on the resin region 20. The resin regions 20 in a thick type and a thin type were prepared.

A tester T was connected to the metal region 30 to confirm the continuity. As a result, it has been found that the mixed region 40 of the resin region 20 and the metal region 30 is non-conductive. Further, it has been found that the conductivity is less likely obtained with the thicker resin region 20 than the thinner resin region 20. It is speculated that the thicker the resin region is, the more the heat energy is required for curing (the harder it is to cure the resin), creating more uncured parts of the resin region, which causes the resin to get into space between the metal particles and inhibit the conductivity between the metal particles, resulting in the mixed region 40 with no conductivity.

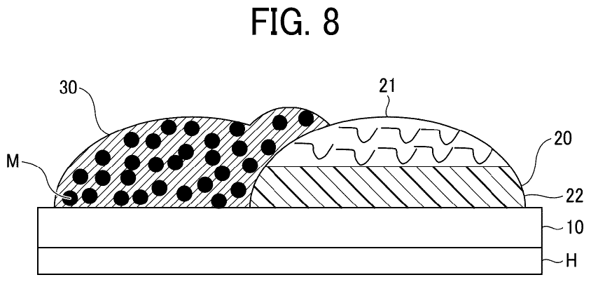

This result suggests that providing the resin region 20 of the mixed region 40 with an uncured portion 21 of the resin makes it possible to create the non-conductive metal region 30 as illustrated in FIG. 8. Further, in this experiment, the metal region 30 is formed on the resin region 20. However, it is predicted that even when the resin region 20 is formed on the metal region 30, the mixed region 40 can be made non-conductive if the metal region 30 is left uncured, and the resin region 20 is formed on the uncured metal region 30.

In this manner, as illustrated in FIG. 9 and FIG. 16, the metal region 32 excluding the mixed region 40 forms the conductive portion, and the mixed region 40 forms the non-conductive portion. Specifically, the metal region 32 (conductive portion) forms the ring portion CP in the SRR, thereby forming a reactance L. Further, the mixed region 40 (non-conductive portion) forms the split portion NC in the SRR, thereby forming the capacitance C (capacitor) (FIG. 1, FIG. 9, and FIG. 17).

### <Method for Producing Electromagnetic Wave Resonant Structure>

The electromagnetic wave resonant structure can be produced by any method. However, the conductive portion can be formed by discharging the conductive ink, and the non-conductive portion can be formed by discharging the non-conductive ink. In this case, the conductive portion and/or the non-conductive portion are preferably formed by inkjet. Further, the conductive portion is preferably formed by the coffee stain effect.

For example, as illustrated in FIG. 3, an inkjet device is used that includes a resin ink discharge head V1, a metal ink discharge head V2, and a conveyance mechanism capable of performing printing on the entire substrate 10. This inkjet device includes a heater H for drying the ink that has been discharged and allowed to land on the substrate 10. From the viewpoint of drying efficiency, the heater H is preferably a stage heater. However, a hot air heater, an IR heater, an UV lamp, or a flash lamp may also be used.

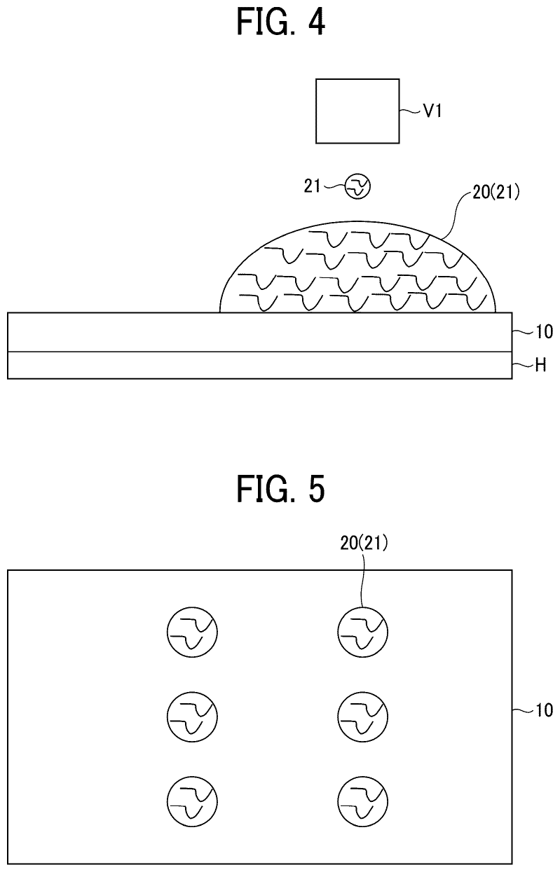

As illustrated in FIG. 3, FIG. 4, and FIG. 5, the resin ink 21 including a resin (e.g., a thermoplastic resin) that forms the resin region 20 is discharged from the discharge head V1 by an inkjet method onto the substrate 10 heated by the heater H. Further, as illustrated in FIG. 3, FIG. 6, and FIG. 7, the metal ink 31 including the metal particle that forms the metal region 30 is discharged from the discharge head V2 using the inkjet method.

In the first embodiment, the resin ink 21 is discharged from the discharge head V1 and allowed to land on the substrate 10. Next, as illustrated in FIG. 7 and FIG. 8, the metal ink 31 is discharged from the discharge head V2 to create a pattern in which a part of the metal ink 31 overlaps a part of the resin ink 21.

During this process, the metal ink 31 is allowed to land so as to overlap the uncured resin ink 21. As a result, the resin ink 21 gets into space between the metal particles (metal M1) in the metal ink 31 and inhibits their conductivity, thereby forming the non-conductive mixed region 40 (a region where the portion 33 of the metal region 30 overlaps the portion 23 of the resin region 20).

Further, the particles of the heated metal ink 31 gather around the periphery due to the coffee stain effect, resulting in forming an SRR pattern including the mixed region 40 as illustrated in FIG. 9 and FIG. 10.

Note that the heating temperature of the resin ink 21 and the metal ink 31 is not particularly limited, and may be any temperature that allows the resin region 20 and the metal region 30 to be formed by the resin ink 21 and the metal ink 31 used. However, the heating temperature is preferably a temperature at which, when the metal ink 31 is cured to form the metal region 30, the resin region 20 is formed such that a part of the resin ink 21 remains uncured.

Further, in order to fully cure the resin region 20 (so that there is no uncured part), the resin region 20 is further dried in an oven or the like. The drying temperature may be freely determined. However, the drying temperature is, for example, 100° C. to 300° C. Further, the drying time may be freely determined. However, the drying time is, for example, 10 minutes to 3 hours. When using a photo-curable (e.g., UV-curable) resin ink, UV irradiation is used. The irradiation time may be freely determined depending on the type of resin ink.

In the first embodiment, a part of the metal ink 31 overlaps the partially cured resin ink 21 discharged onto the substrate 10. In this state, as illustrated in FIG. 9 and FIG. 10, the metal ink 31 is cured due to the coffee stain effect, thereby forming the ring-shaped metal region 30, while the resin ink forms the resin region (cured portion) 20 including a portion 22 that does not form the mixed region 40, and the portion 23 that forms the mixed region 40 with the portion 33 of the metal region 30.

In the electromagnetic wave resonant structure 100 of the first embodiment, the metal ink 31 is discharged after the resin ink 21 is discharged as illustrated in FIG. 4 to FIG. 10.

However, the timing of discharging the resin ink 21 and the metal ink 31 is not limited thereto. For example, the resin ink 21 may be discharged after the metal ink 31 is discharged, or the resin ink 21 and the metal ink 31 may be discharged simultaneously.

### Second Embodiment

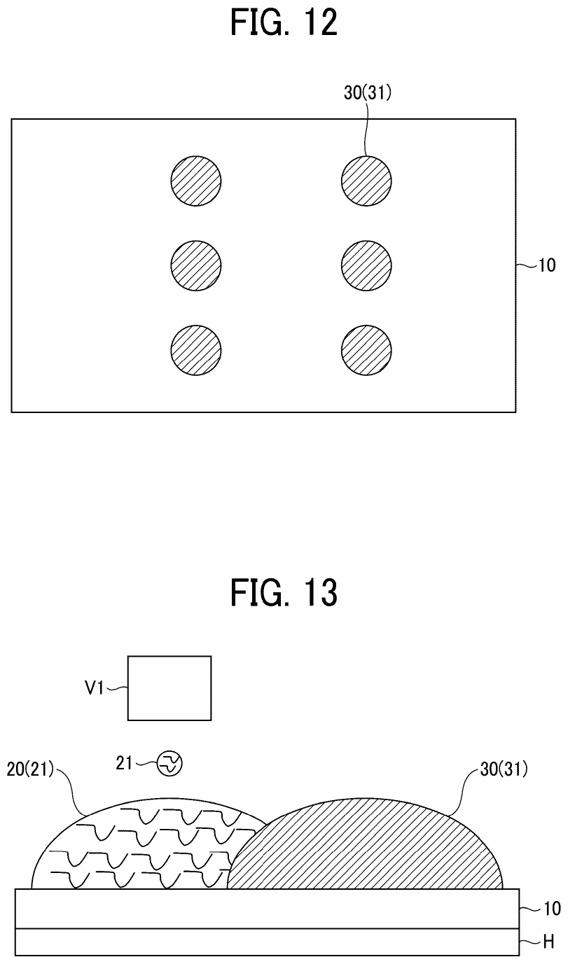

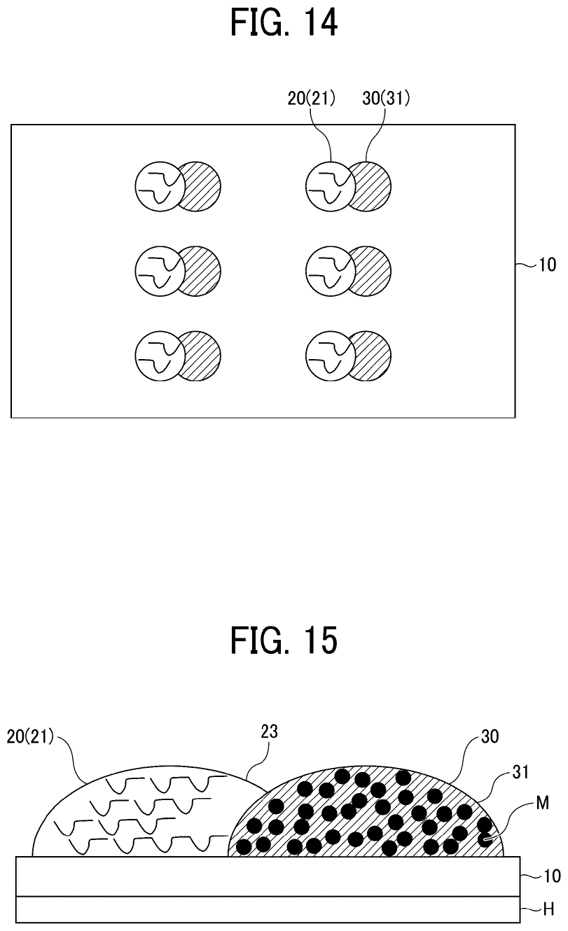

In an electromagnetic wave resonant structure 200 of the second embodiment, as illustrated in FIG. 11 to FIG. 17, after the metal ink 31 is discharged, the resin ink 21 is discharged, thereby producing the electromagnetic wave resonant structure in which the portion 33 of the metal region 30 is taken into the resin region 20.

In the second embodiment, the metal ink 31 is discharged from the discharge head V2 and allowed to land on the substrate 10. Next, the resin ink 21 is discharged from the discharge head V1 to create a pattern in which a part of the resin ink 21 overlaps a part of the metal ink 31. During this process, the resin ink 21 is allowed to land so as to overlap the uncured metal ink 31. As a result, the resin ink 21 gets into space between the metal particles M1 in the metal ink 31 and inhibits their conductivity, thereby forming the non-conductive mixed region 40 (a region where the portion 33 of the metal region 30 is taken into the portion 23 of the resin region 20).

Further, the particles of the heated metal ink 31 gather around the periphery due to the coffee stain effect, resulting in forming an SRR pattern including the mixed region 40 as illustrated in FIG. 16 and FIG. 17.

Note that the heating temperature of the resin ink 21 and the metal ink 31 is not particularly limited in the second embodiment. However, the heating temperature is preferably a temperature at which, when the metal ink 31 is cured to form the metal region 30, the resin region 20 is formed such that a part of the resin ink 21 remains uncured.

Further, in the second embodiment, the resin region 20 is fully cured (so that there is no uncured part).

As described above, the electromagnetic wave resonant structure 100 of the first embodiment and the electromagnetic wave resonant structure 200 of the second embodiment each includes the conductive portion and the non-conductive portion, and the non-conductive portion includes the region (mixed region 40) in which the portion 23 (insulator) of the resin region 20 is mixed in the portion 33 (a part of the conductive portion) of the metal region 30.

In this manner, the conductive portion of the electromagnetic wave resonant structures 100 and 200 can be applied to the ring portion (conductive portion) of the SRR, and the non-conductive portion of the electromagnetic wave resonant structures can be applied to the split portion (non-conductive portion) of the SRR. Thus, the electromagnetic wave resonant structure of the present embodiment can form a resonator element such as the SRR that absorbs terahertz waves and can be expected to be used as a metamaterial.

Further, in the electromagnetic wave resonant structures 100 and 200, the mixed region 40 is the region where the ring-shaped metal region 30 (conductive portion) in the plan view and the circularly shaped resin region 20 (insulator) in the plan view overlap. This makes it possible to apply the electromagnetic wave resonant structure including the metal region 32 (conductive portion) and the mixed region 40 (non-conductive portion) to the SRR including the ring portion (conductive portion) and the split portion (non-conductive portion).

Further, in the method for producing the electromagnetic wave resonant structure of the present embodiment, as described above, the conductive portion is formed by discharging the conductive ink, and the non-conductive portion is formed by discharging the non-conductive ink. This makes it possible to form the conductive portion and the non-conductive portion in the obtained electromagnetic wave resonant structure. Further, this makes it possible to form, in the non-conductive portion included in the electromagnetic wave resonant structure, the region (mixed region 40) where the portion 23 (insulator) of the resin region 20 is mixed in the portion 33 (a part of the conductive portion) of the metal region 30.

In this manner, in the obtained electromagnetic wave resonant structure, the conductive portion can be applied to the ring portion (conductive portion) of the SRR, and the non-conductive portion can be applied to the split portion (non-conductive portion) of the SRR.

Thus, according to the method for producing the electromagnetic wave resonant structure of the present embodiment, it is possible to produce a resonator element such as the SRR that absorbs terahertz waves.

Further, in the method for producing the electromagnetic wave resonant structure of the present embodiment, as described above, the conductive portion is formed by the coffee stain effect. This makes it possible to provide the electromagnetic wave resonant structure that can absorb electromagnetic waves with the structure that uses the coffee stain effect. Thus, the obtained electromagnetic wave resonant structure can form a resonator element such as the SRR that absorbs terahertz waves and can be expected to be used as a metamaterial.

Note that the SRR is generally produced using optical lithography. The optical lithography is performed in a vacuum condition, thus requiring a large-scale equipment. Further, in the optical lithography, changing the diameter of the SRR ring or the distance of the split portion requires multiple expensive masks.

On the other hand, in the method for producing the electromagnetic wave resonant structure of the present embodiment, as described above, the conductive portion and/or the non-conductive portion are formed by inkjet, making it possible to produce the SRR structure at room temperature in the atmosphere without requiring a large-scale equipment. Further, inkjet does not require a mask or a complicated process and can print the SRR designed using a computer on demand.

### Third Embodiment

In an electromagnetic wave resonant structure 300 of a third embodiment illustrated in FIG. 18 to FIG. 20, the above-described metal region 30, resin region 20, and mixed region 40 are formed on the substrate 10.

The shape, structure, and size of the substrate 10 are not particularly limited and can be appropriately selected according to the purpose. A material for the substrate 10 is not particularly limited and can be appropriately selected according to the purpose. However, for example, a glass substrate, a ceramic substrate, a plastic substrate, a film substrate, or the like can be used.

The glass substrate is not particularly limited and can be appropriately selected according to the purpose. However, examples of the glass substrate include alkali-free glass and silica glass. Further, the plastic substrate or the film substrate is not particularly limited and can be appropriately selected according to the purpose. However, examples of the plastic substrate or the film substrate include polycarbonate (PC), polyimide (PI), polyethylene terephthalate (PET), and polyethylene naphthalate (PEN).

A region on the surface of the substrate 10, on which the mixed region 40 (non-conductive portion) is formed, has been subjected to a hydrophilic treatment. Here, a hydrophilic agent used in the hydrophilic treatment is not particularly limited. However, examples thereof include a silicate compound, a silica-based hydrophilic agent, a fluorine-based hydrophilic agent, a titanium oxide-based photocatalyst, and a quaternary ammonium salt-containing polymer.

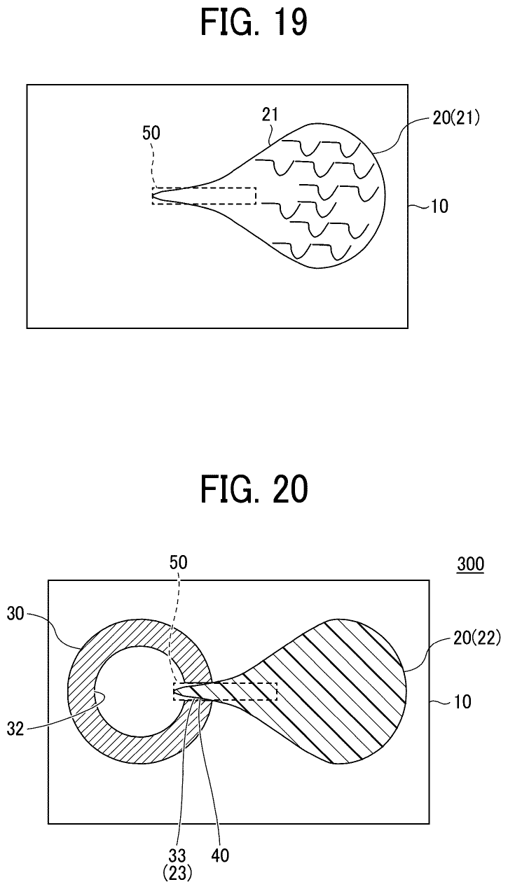

In the present embodiment, a region 50 illustrated in FIG. 18 on the surface of the substrate 10 where the mixed region 40 (non-conductive portion) is formed is subjected to the hydrophilic treatment in advance, and the resin ink 21 is discharged (allowed to land) onto the substrate 10 so that the non-conductive portion (split portion NC of SRR) is positioned at this region 50 (hydrophilic portion) as illustrated in FIG. 19, making it possible to form a pattern of the resin ink 21 in the non-conductive portion by capillary action as illustrated in FIG. 20.

In this manner, in the third embodiment, it is easy to control the distance (interval) of the non-conductive portion NC (split portion of SRR), that is, a capacitance C component.

### Fourth Embodiment

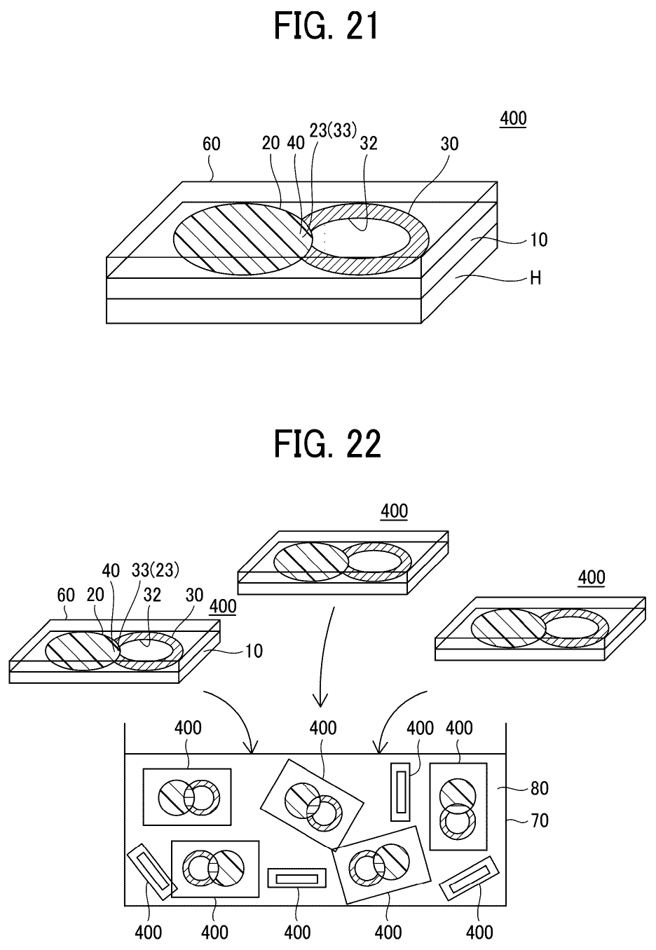

An electromagnetic wave resonant structure 400 of a fourth embodiment further includes a covering layer 60 as illustrated in FIG. 21.

The covering layer 60 covers the electromagnetic wave resonant structure 100 or the electromagnetic wave resonant structure 200 described above. Note that, in the present embodiment, the entire electromagnetic wave resonant structure is covered with the covering layer 60. However, a form of the covering layer 60 is not limited to this, and a part of the electromagnetic wave resonant structure may be covered by the covering layer 60.

The thickness of the covering layer 60 is not particularly limited and can be appropriately selected according to the purpose.

A material for the covering layer 60 is not particularly limited. However, examples thereof include a urethane resin, an acrylic resin, an epoxy resin, a polyimide resin, a polyamide resin, and a polyimide amide resin. These resins may be used alone or in combination of two or more.

If the electromagnetic wave resonant structure with the SRR structure formed on the substrate 10 warps due to the difference in linear expansion coefficient with the substrate 10, it becomes difficult to keep the distance of the SRR split portion (capacitance C component) constant. On the other hand, in the electromagnetic wave resonant structure 400 of the fourth embodiment, the warping of the electromagnetic wave resonant structure can be prevented by covering it with the covering layer 60, making it easy to control the distance of the SRR split portion (capacitance C component).

### Fifth Embodiment

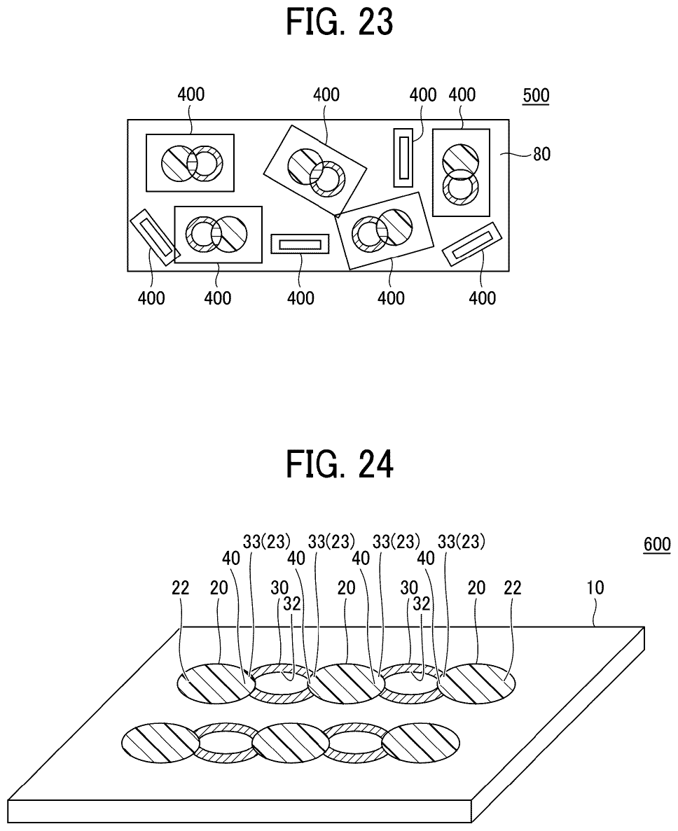

In an electromagnetic wave resonant structure 500 of a fifth embodiment illustrated in FIG. 23, a plurality of electromagnetic wave resonant structures are randomly disposed. In the present embodiment, as illustrated in FIG. 22, the plurality of electromagnetic wave resonant structures are molded using a mold resin 80 filled in a mold 70. Note that the electromagnetic wave resonant structure 500 is released from the mold 70 after being molded.

Note that the electromagnetic wave resonant structure to be molded may be the electromagnetic wave resonant structure 100 or the electromagnetic wave resonant structure 200 described above. However, from the viewpoint of product stability, the electromagnetic wave resonant structure 400 in which warping is prevented is preferably used.

A material for the mold resin 80 is not particularly limited. However, examples thereof include an unsaturated polyester, an epoxy resin, and a silicone resin.

In the electromagnetic wave resonant structure 500 of the fifth embodiment, the plurality of electromagnetic wave resonant structures are randomly disposed in this manner, making it possible to prevent the incident angle dependency of electromagnetic waves. Further, this makes it possible to perform the prevention of the incident angle dependency of electromagnetic waves on demand.

### Sixth Embodiment

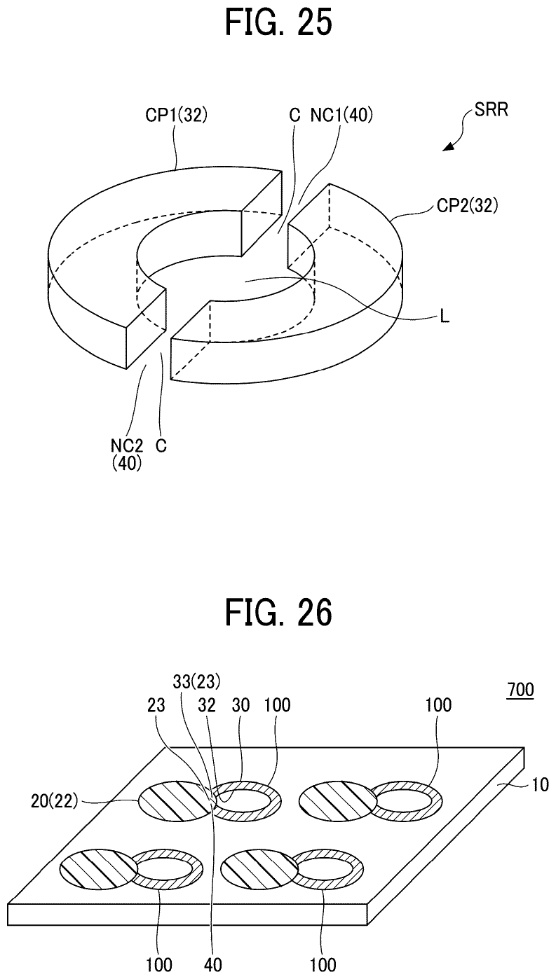

An electromagnetic wave resonant structure 600 of a sixth embodiment includes a plurality of mixed regions 40 as illustrated in FIG. 24. In the present embodiment, one electromagnetic wave resonant structure 600 is provided with a plurality of metal regions 32 and a plurality of mixed regions 40. As illustrated in FIG. 25, each of the metal regions 32 includes two conductive portions CP1 and CP2 and each of the mixed regions 40 includes two non-conductive portions NC1 and NC2 (capacitances C).

The production of the electromagnetic wave resonant structure 600 is the same as that of the electromagnetic wave resonant structures 100 and 200 (FIG. 4 to FIG. 17) except that two drops of the resin ink 21 are discharged and allowed to land on the substrate 10 for each drop of the metal ink 31.

In the electromagnetic wave resonant structure 600 of the sixth embodiment, each of the mixed regions 40 (non-conductive portions) includes two non-conductive portions NC1 and NC2 as described above. Thus, when a plurality of electromagnetic wave resonant structures are disposed on the same plane, the layout efficiency can be improved. Further, two capacitances C can be provided in one electromagnetic wave resonant structure 600, making it possible to cope with a frequency shift.

### Seventh Embodiment

In an electromagnetic wave resonant structure 700 of a seventh embodiment, a plurality of electromagnetic wave resonant structures 100 are disposed on the same plane as illustrated in FIG. 26. In the seventh embodiment, the plurality of electromagnetic wave resonant structures 100 are regularly disposed on the substrate 10 at equal intervals in the front, back, left, and right directions, but they may be disposed irregularly.

In the electromagnetic wave resonant structure 700 of the seventh embodiment, the plurality of electromagnetic wave resonant structures 100 are disposed on the same plane, making it possible to increase the absorption amount of electromagnetic waves. Further, when the plurality of electromagnetic wave resonant structures 100 are regularly disposed on the same plane, it becomes possible to absorb electromagnetic waves with a periodic pattern.

### Eighth Embodiment

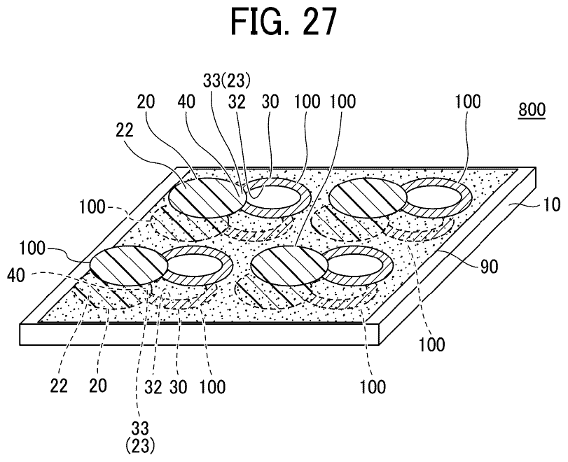

In an electromagnetic wave resonant structure 800 of an eighth embodiment, a plurality of electromagnetic wave resonant structures 100 are laminated in the vertical direction as illustrated in FIG. 27. In the eighth embodiment, a plurality of electromagnetic wave resonant structures 700 are further laminated on top of the layer of the plurality of electromagnetic wave resonant structures 700 in the seventh embodiment with an isolation layer 90 therebetween. Note that in the eighth embodiment, the plurality of electromagnetic wave resonant structures 100 are regularly disposed on the substrate 10 at equal intervals in the top, bottom, front, back, left, and right directions, but they may be disposed irregularly.

The thickness of the isolation layer 90 is not particularly limited, and the thickness may be such that the electromagnetic wave resonant structures 700 are not connected to each other at the top and bottom.

A material for the isolation layer 90 is not particularly limited. However, examples thereof include a urethane resin, an acrylic resin, an epoxy resin, a polyimide resin, a polyamide resin, and a polyimide amide resin. These resins may be used alone or in combination of two or more.

In the electromagnetic wave resonant structure 800 of the eighth embodiment, the plurality of electromagnetic wave resonant structures 100 are laminated in the vertical direction, making it possible to increase the absorption amount of electromagnetic waves.

Further, when the plurality of electromagnetic wave resonant structures 100 are regularly disposed on the same plane, it becomes possible to absorb electromagnetic waves with a periodic pattern.

### <Electronic Component>

Note that, in the electromagnetic wave resonant structures 100, 200, 300, 400, 500, 600, 700, and 800, as described above, the metal region 32 (conductive portion) can form the reactance L, and the mixed region 40 (non-conductive portion) can form the capacitance C (capacitor) (see FIG. 1, FIG. 9, and FIG. 17). Thus, these electromagnetic wave resonant structures can be applied to an electronic component such as SRR.

### <Conductive Structure>

FIG. 28 is a diagram illustrating a conductive structure 900 of the present embodiment. The conductive structure 900 includes a conductive portion and a non-conductive portion on the substrate 10 having a circuit thereon (hereinafter “circuit board 10”). The circuit board 10 is not particularly limited. However, for example, a printed circuit board may be used.

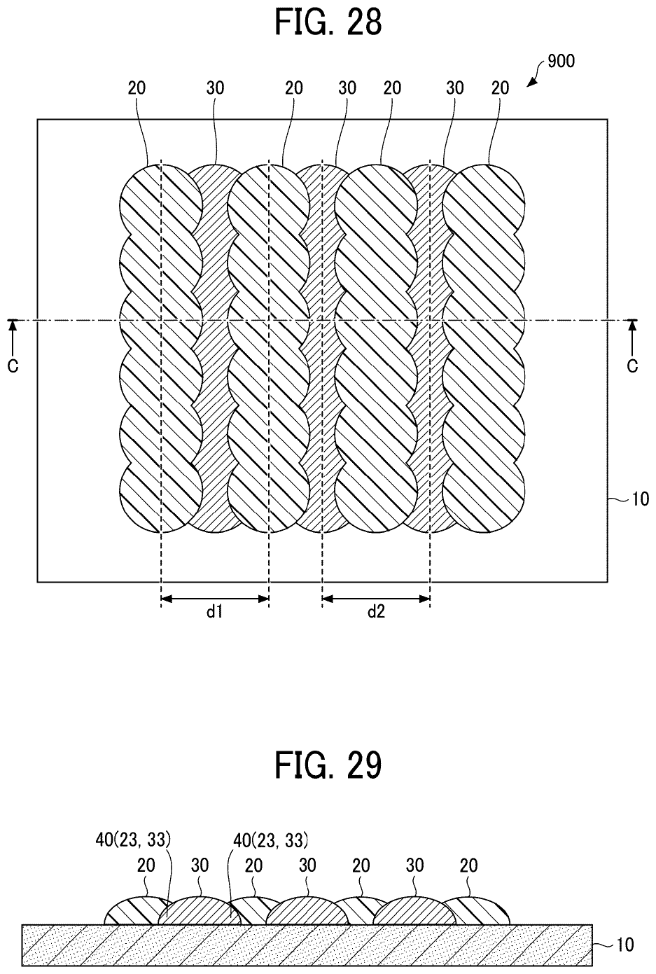

The conductive portion is, like the electromagnetic wave resonant structure described above, a region formed by a conductor and preferably comprises a metal. In the present embodiment, for example, as illustrated in FIG. 28 and FIG. 29, the above-mentioned conductive ink (metal ink 31) is discharged onto the circuit board 10, and as this conductive ink is cured, the metal region 30 including the metal M is formed as an example of the conductive portion.

A form of the conductive portion is not particularly limited. In the present embodiment, for example, the conductive portions (metal regions 30) are formed in stripes on the circuit board 10 at intervals of a pitch d1.

The non-conductive portion is, like the electromagnetic wave resonant structure described above, a region that does not exhibit conductivity and preferably comprises a resin.

In the present embodiment, for example, as illustrated in FIG. 28 and FIG. 29, the above-mentioned non-conductive ink (resin ink 21) is discharged onto the circuit board 10, and as this non-conductive ink is cured, the resin region 20 is formed as an example of the non-conductive portion.

A form of the non-conductive portion is not particularly limited. In the present embodiment, for example, the non-conductive portions (resin regions 20) are formed in stripes on the circuit board 10 at intervals of a pitch d2. During this process, the non-conductive portions are formed such that the portions 23 of the non-conductive portions (resin regions 20) overlap the portions 33 of the conductive portions (metal regions 30) (FIG. 29).

The non-conductive portions each includes a region (mixed region 40) in which an insulator is mixed in a part of the conductive portion. Specifically, as illustrated in FIG. 29, like the electromagnetic wave resonant structure described above, the non-conductive portion (resin region 20) includes the region (mixed region 40) in which the portion 23 (insulator) of the resin region 20 is mixed in the portion 33 of the conductive portion (metal region 30).

Note that a form of the mixed region in the conductive structure is not limited to the form of the mixed region 40 of the conductive structure 900 illustrated in FIG. 29. The mixed region may be formed such that the portion 23 of the non-conductive portion (resin region 20) overlaps the portion 33 of the conductive portion (metal region 30).

As described above, the conductive structure 900 of the present embodiment includes the conductive portions and the non-conductive portions on the circuit board 10, and each non-conductive portion includes the region (mixed region 40) in which the portion 23 (insulator) of the resin region 20 is mixed in the portion 33 (a part of the conductive portion) of the metal region 30. Thus, the conductive structure 900 can be applied to various uses. For example, it is expected that the conductive structure 900 can be applied to: an electronic circuit, an electronic device, or the like produced using printed electronics; or a storage battery, a capacitor, or the like produced using inkjet printing technology.

Embodiments of the present invention include, for example, the following aspects.

### (Aspect 1)

An electromagnetic wave resonant structure including a conductive portion and a non-conductive portion, in which the non-conductive portion includes a mixed region of a part of the conductive portion and an insulator.

### (Aspect 2)

The electromagnetic wave resonant structure according to Aspect 1, in which the conductive portion has a ring shape in a plan view.

### (Aspect 3)

The electromagnetic wave resonant structure according to Aspect 1 or 2, in which the conductive portion comprises a metal.

### (Aspect 4)

The electromagnetic wave resonant structure according to any one of Aspects 1 to 3, in which the insulator comprises a resin.

### (Aspect 5)

The electromagnetic wave resonant structure according to any one of Aspects 1 to 4, in which, in the mixed region, the conductive portion having the ring shape in the plan view and the insulator overlap.

### (Aspect 6)

The electromagnetic wave resonant structure according to any one of Aspects 1 to 5, further including a substrate on which the conductive portion and the non-conductive portion are disposed in which a region of a surface of the substrate on which the non-conductive portion is disposed has a hydrophilic treatment.

### (Aspect 7)

The electromagnetic wave resonant structure according to any one of Aspects 1 to 6, further including a covering layer that covers an entire or a part of the electromagnetic wave resonant structure.

### (Aspect 8)

The electromagnetic wave resonant structure according to any one of Aspects 1 to 7, in which a plurality of electromagnetic wave resonant structures including said electromagnetic wave resonant structure are randomly disposed.

### (Aspect 9)

The electromagnetic wave resonant structure according to any one of Aspects 1 to 8, wherein the electromagnetic wave resonant structure includes two non-conductive portions including said non-conductive portion.

### (Aspect 10)

The electromagnetic wave resonant structure according to any one of Aspects 1 to 9, in which a plurality of electromagnetic wave resonant structures including said electromagnetic wave resonant structure are disposed on the same plane.

### (Aspect 11)

The electromagnetic wave resonant structure according to any one of Aspects 1 to 10, in which a plurality of electromagnetic wave resonant structures including said electromagnetic wave resonant structure are laminated on one another in a vertical direction.

### (Aspect 12)

A method for producing the electromagnetic wave resonant structure according to any of Aspects 1 to 11, including discharging a conductive ink to form the conductive portion, and discharging a non-conductive ink to form the non-conductive portion.

### (Aspect 13)

The method according to Aspect 12, in which the conductive portion is formed by a coffee stain effect.

### (Aspect 14)

The method according to Aspect 13, in which at least one of the conductive portion and the non-conductive portion is formed by inkjet.

### (Aspect 15)

An electronic component including the electromagnetic wave resonant structure according to any of Aspects 1 to 11.

### (Aspect 16)

A conductive structure including a circuit board having a conductive portion and a non-conductive portion thereon, in which the non-conductive portion includes a mixed region of a part of the conductive portion and an insulator.

The embodiments of the present invention have been described above. However, the present invention is not limited to specific embodiments, and various modifications and changes can be made within the scope of the invention described in the claims.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

1. An electromagnetic wave resonant structure comprising:
a conductive portion; and
a non-conductive portion,
the non-conductive portion including a mixed region of a part of the conductive portion and an insulator.

2. The electromagnetic wave resonant structure according to claim 1, wherein the conductive portion has a ring shape in a plan view.

3. The electromagnetic wave resonant structure according to claim 1, wherein the conductive portion comprises a metal.

4. The electromagnetic wave resonant structure according to claim 1, wherein the insulator comprises a resin.

5. The electromagnetic wave resonant structure according to claim 1, wherein, in the mixed region, the conductive portion having a ring shape in a plan view and the insulator overlap one another.

6. The electromagnetic wave resonant structure according to claim 1, further comprising a substrate on which the conductive portion and the non-conductive portion are disposed,
wherein a region of a surface of the substrate on which the non-conductive portion is disposed has a hydrophilic treatment.

7. The electromagnetic wave resonant structure according to claim 1, further comprising a covering layer that covers an entire or a part of the electromagnetic wave resonant structure.

8. The electromagnetic wave resonant structure according to claim 1, wherein a plurality of electromagnetic wave resonant structures including said electromagnetic wave resonant structure are randomly disposed.

9. The electromagnetic wave resonant structure according to claim 1, wherein the electromagnetic wave resonant structure includes two non-conductive portions including said non-conductive portion.

10. The electromagnetic wave resonant structure according to claim 1, wherein a plurality of electromagnetic wave resonant structures including said electromagnetic wave resonant structure are disposed on the same plane.

11. The electromagnetic wave resonant structure according to claim 1, wherein a plurality of electromagnetic wave resonant structures including said electromagnetic wave resonant structure are laminated on one another in a vertical direction.

12. A method for producing the electromagnetic wave resonant structure according to claim 1, the method comprising:
discharging a conductive ink to form the conductive portion; and
discharging a non-conductive ink to form the non-conductive portion.

13. The method according to claim 12, wherein the conductive portion is formed by a coffee stain effect.

14. The method according to claim 13, wherein at least one of the conductive portion and the non-conductive portion is formed by inkjet.

15. An electronic component comprising the electromagnetic wave resonant structure according to claim 1.

16. A conductive structure comprising:
a circuit board having a conductive portion and a non-conductive portion thereon,
the non-conductive portion including a mixed region of a part of the conductive portion and an insulator.
